(19) United States
(12) Patent Application Publication
(10) Pub. No.: US 2003/0216025 A1
(43) Pub. Date: Nov. 20, 2003

(54) Wafer level electroless copper metallization and bumping process, and plating solutions for semiconductor wafer and microchip

(76) Inventors: Haijing Lu, Singapore (SG); Hao Gong, Singapore (SG); Stephen Choo Khuen Wong, Singapore (SG)

Correspondence Address: Killworth, Gottman, Hagan & Schaeff, L.L.P., Suite 500, One Dayton Centre, Dayton, OH, 45402-2023, US

(21) Appl. No.: 10/439,682

(22) Filed: May 16, 2003

Related U.S. Application Data
(60) Provisional application No. 60/378,049, filed on May 16, 2002.

(51) Int. Cl. H01L 21/44

(52) U.S. Cl. 438/614; 438/687

(57) ABSTRACT

A process is used to produce copper bumps on a semiconductor chip or a wafer containing several microchips. The chip or wafer has a layer incorporating a plurality semiconductor devices and a passivation layer having openings. Conductive pads within the openings and are in contact with the semiconductor devices. In the process, a conductive adhesive material is deposited onto the conductive pads to form adhesion layers. A conductive metal is deposited onto the adhesion layers to form barrier layers and the passivation layer is subjected to an acid dip solution to remove particles of the conductive adhesive material which can be attached to the passivation layer. Copper is then deposited onto the barrier layers to form the copper bump. Each one of the deposition steps are performed electrolessly. Furthermore, plating solutions and a wafer and a microchip produced by the above process and are provided.

### RELATED APPLICATION

This Application claims the benefit of U.S. Provisional Application No. 60/378,049 filed May 16, 2002.

### FIELD OF THE INVENTION

The invention relates to wafer bumping technology in semiconductors. In particular, the invention relates to an electroless deposition process of producing copper bumps on a microchip or a wafer containing a plurality of microchips.

### BACKGROUND OF THE INVENTION

Electroless deposition is becoming a more and more attractive technology in the wafer bumping industry as it offers many advantages over existing electrolytic plating technologies. In particular, electroless deposition has the advantages of being maskless and having a low-cost, shorter process steps, good uniformity and good gap filling ability over electrolytic plating technologies. These advantages are particularly important in UBM (Under-Bump-Metal) applications in wafer bumping. An electroless Nickel bumping process has been developed for producing Nickel bumps at a low-cost; however, the process has not yet been adapted for mass production. Furthermore, Nickel is not particularly well-suited for bumping applications as it has a high hardness and tends to have high intrinsic stress for a thickness of deposited nickel above 1 μm. This results in limited applicability of electroless Nickel deposition on wafers as the underlying semiconductor structure of the wafers are usually very fragile and sensitive to stress.

Copper offers several intrinsic properties as an alternative metal in bumping applications. In particular, when compared to Nickel, Copper has a higher electrical conductivity, a higher thermal conductivity, a lower melting point, a lower thermal expansion co-efficient and is a more ductile metal. In addition, Copper is much cheaper than Nickel or other metals, such as Tin, Lead and Gold, used in electrolytic bumping applications. As such, the development of electroless copper bumping processes on wafers is very important in the wafer bumping industry.

Furthermore, copper metal pads on silicon wafers are gradually being introduced in silicon integrated circuits metallization schemes as replacements for aluminum pads. Aluminum and its alloys suffer from problems of high RC (Resistance-Capacitance) delay, high electro-migration and poor stress resistance. Copper, on the other, has been generally recognized as a new metallization material in place of Aluminum for the next generation of Silicon wafers. Although the use of Copper for on-chip interconnects has only recently been implemented by the semiconductor industry, Copper has been used extensively in providing a solderable surface for flip-chip packaging and interconnect applications for many years. It is, therefore, significant to develop a process of electroless copper bumping on wafer level to satisfy these demands.

### SUMMARY OF THE INVENTION

A process is used to produce copper bumps on a semiconductor chip or wafer containing the microchip. The chip or wafer has a layer incorporating a plurality of semiconductor devices and a passivation layer having openings. Conductive pads within the openings are in contact with the semiconductor devices. In the process, a conductive adhesive material is deposited onto the conductive pads to form adhesion layers. A conductive metal is deposited onto the adhesion layers to form barrier layers and the passivation layer is subjected to an acid dip solution to remove particles of the conductive adhesive material and the conductive metal which may be attached to the passivation layer. Copper is then deposited onto the barrier layers to form the copper bumps. Each one of the deposition steps are performed electrolessly providing complete growth of the bumps electrolessly. Furthermore, plating solutions and a wafer and a microchip produced by the above process and are provided.

In accordance with a first broad aspect, the invention provides a process for producing copper bumps on a semiconductor wafer incorporating a plurality of semiconductor devices. The semiconductor wafer also has a passivation layer having openings and conductive pads, within the openings, in contact with the semiconductor devices. The process includes the steps of: performing electroless deposition of a conductive adhesive material onto the conductive pads to form adhesion layers; performing electroless deposition of a conductive metal onto the adhesion layers to form barrier layers; subjecting the passivation layer to an acid dip solution to remove any particles containing at least one of the conductive adhesive material and the conductive metal, which may be attached to the passivation layer; and performing electroless deposition of Copper onto the barrier layers to form the copper bumps.

In some embodiments of the invention, the process includes applying a resist on a backside of the semiconductor wafer prior to the electroless deposition of the conductive adhesive material onto the conductive pads.

In some embodiments of the invention, the process includes removing oxidation layers on the conductive pads using an alkaline cleaner prior to the electroless deposition of the conductive adhesive material onto the conductive pads.

In some embodiments of the invention, the electroless deposition of the conductive adhesive material onto the conductive pads includes electrolessly depositing Zinc onto the conductive pads. This may be performed by immersing the semiconductor wafer in an adhesive plating solution containing Zn⁺⁺ (Zinc++) ions and allowing the Zn⁺⁺ ions to absorb onto the conducting pads in a reaction with Al (Aluminium) in the conductive pads.

In some embodiments of the invention, the electroless deposition of the conductive metal onto the adhesion layers includes electrolessly depositing Pd (Palladium) onto the adhesion layers. The Pd may be electrolessly deposited onto the adhesion layers by immersing the semiconductor wafer in a barrier plating solution containing Pd⁺⁺ ions and allowing the Pd⁺⁺ ions to absorb onto the adhesive layers by reacting with Zn in the adhesion layers.

In some embodiments of the invention, the electroless deposition of the conductive metal onto the adhesion layers includes electrolessly depositing Ni (Nickel) onto the adhesion layers.

In some embodiments of the invention, the Pd is electrolessly deposited onto the adhesion layers by immersing the semiconductor wafer in a barrier plating solution containing a reducing agent for electrolessly depositing additional Pd onto the adhesion layers in a follow-up reaction.

In some embodiments of the invention, the electroless deposition of Copper onto the barrier layers is performed by immersing the semiconductor wafer in a copper plating solution containing copper ions, Sodium Hydroxide, a complexing agent and a reducing agent.

In some embodiments of the invention, the process includes performing electroless deposition of an anti-tarnish chemical to produce a cap layer over the copper bumps and the passivation layer.

In accordance with a second broad aspect, the invention provides a semiconductor chip incorporating a plurality of semiconductor devices. The semiconductor chip also has a passivation layer having openings and conductive pads, within the openings, in contact with the semiconductor devices for providing contacts between the semiconductor devices and outside circuitry. Within each one of the openings, the semiconductor chip has: an adhesion layer of a conductive adhesive material in contact with a respective one of the conducting pads; a barrier layer of a conductive metal in contact with the adhesion layer; and a layer of Copper in contact with the barrier layer, the layer of Copper forming a copper bump.

In accordance with a third broad aspect, the invention provides a semiconductor wafer which contains a plurality of the above semiconductor chip.

In accordance with a fourth broad aspect, the invention provides a plating solution for electrolessly depositing Copper onto a layer of Nickel or Palladium. The plating solution includes: Copper ions for a reaction with the Nickel or Palladium for deposition of Copper; and an alkaline, a completing agent and a reducing agent for additional deposition of the Copper in a follow-up reaction.

In some embodiments of the invention, the plating solution includes a surface control agent for providing a smooth surface of the Copper being deposited. The surface control agent may include at least one of Tetramethylammonium and 2,2′-dipyridyl.

In accordance with a fifth broad aspect, the invention provides a plating solution for electrolessly depositing a layer of Nickel or Palladium onto a layer of Zinc. The plating solution includes: Nickel or Palladium ions for a reaction with the Zinc for deposition of Nickel or Palladium; and a reducing agent for additional deposition of the Nickel or Palladium in a follow-up reaction.

In some embodiments of the invention, the plating solution includes Ammonium Chloride, Ammonia and Hydrogen Chloride.

### BRIEF DESCRIPTION OF THE DRAWINGS

Preferred embodiments of the invention will now be described with reference to the attached drawings in which:

FIG. 1 is a top view of a semiconductor chip, on a Si (Silicon) wafer, having a number of copper bumps arranged in a predetermined pattern as produced according to one embodiment of the invention;

FIG. 2 is a schematic cross-sectional view of one of the copper bumps of the semiconductor chip of FIG. 1;

FIG. 3 is a flow chart of a process used to manufacture the copper bump of FIG. 2;

FIG. 4 is a cross-sectional view of the copper bump of FIG. 2 at different steps of the process of FIG. 3;

FIG. 5A is a top view of six copper bumps of the semiconductor chip of FIG. 1;

FIG. 5B is an expanded view of one of the copper bumps of FIG. 5A; and

FIG. 6 is a graph of the height of copper bumps of the semiconductor chip of FIG. 1 plotted as a function of distance along the semiconductor chip, the height being measured using a stylus profilometer;

FIG. 7 is an AFM (Atomic Force Microscopy) surface profile of a portion of a conductive pad of one of the copper bumps of FIG. 5A after an Al (Aluminum) cleaning step;

FIG. 8 is an AFM surface profile of a portion of the pad of FIG. 7 after electroless deposition of Zinc onto the pad;

FIG. 9 is an AFM surface profile of a portion of the pad of FIG. 8 after electroless deposition of Palladium onto the pad;

FIG. 10 is an AFM surface profile of a portion of the copper bump of FIG. 5B; and

FIG. 11 is a photo of the copper bump of FIG. 5B after having applied upon it a shear by a Shear Tester.

### DETAILED DESCRIPTION OF THE PREFERRED EMBODIMENTS

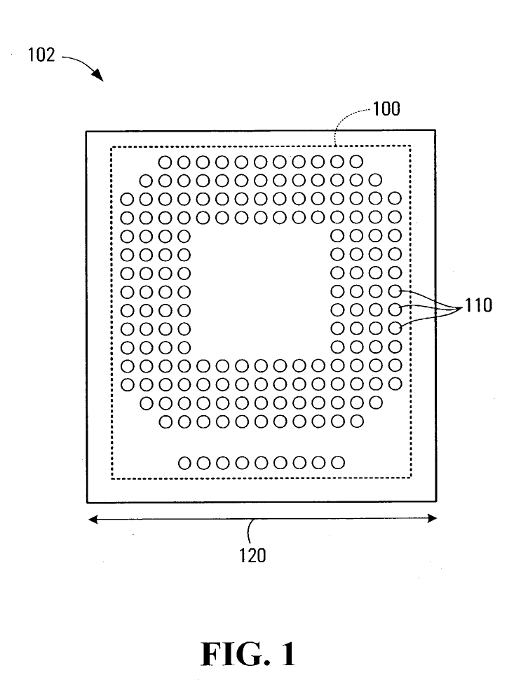

FIG. 1 is a top view of a semiconductor chip 100, on a Si (Silicon) wafer, having a number of copper bumps 110 arranged in a predetermined pattern as produced according to one embodiment of the invention. Only a portion 102 of the silicon wafer is shown.

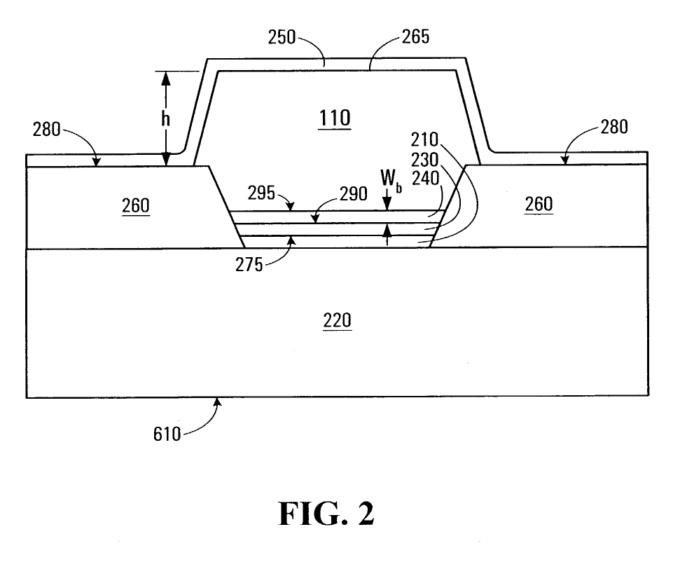

FIG. 2 is a schematic cross-sectional view of one of the copper bumps 110 of the semiconductor chip 100 of FIG. 1. A conductive pad 210 is in contact with a layer 220, of the of semiconductor chip 100, which contains a respective semiconductor device (not shown). An adhesion layer 230 is in contact with the conductive pad 210 and a barrier layer 240 is in contact with the adhesion layer 230. The copper bump 110 is in contact with the barrier layer 240 and has a cap layer 250. A passivation layer 260 isolates the copper bump 110 from other copper bumps 110 of the semiconductor chip 100.

The conductive pad 210 provides an electrical contact with the respective semiconductor device in the layer 220, and the copper bump 110 is used to establish communication between conductive pad 210 (or equivalently, the semiconductor device) and outside circuitry. For example, each copper bump 110 may be used to establish communication between a respective semiconductor device and a printed circuit board (not shown) as part of a large circuit.

In the embodiment of FIG. 2, the conductive pad 210 is made of Al (Aluminium); the adhesion layer 230 is made of Zn (Zinc) and provides adhesion between the conductive pad 210 and the barrier layer 240; the barrier layer 240 is made of Pd (Palladium) and provides a barrier for atoms of the copper bump 110 by preventing copper atoms from penetrating the barrier layer 240 into the adhesion layer 230 and into the conductive pad 210; the copper bump 110 is made of Cu (Copper); and the cap layer 250 is made of an anti-tarnish material (Metex-M667 (MacDermid)) and provides a protection layer, against oxidation, for the copper bump 110. The invention is not limited to the above materials and in other embodiments of the invention, the Aluminium in the conductive pad 210 is made of Copper. In addition, in other embodiments of the invention the Zinc in the adhesion layer 230 is replaced by a conductive adhesive organic material having similar mechanical and electrical properties as well as a similar crystal structure. Similarly, in other embodiments of the invention, the Palladium in the barrier layer 240 is replaced by another metal having similar mechanical and electrical properties as well as a similar crystal structure. In another embodiment of the invention, Nickel replaces Palladium as a material for the barrier layer 240. In yet another embodiment of the invention, both Nickel and Palladium are present in the barrier layer 240. Furthermore, the cap layer 250 is made of any suitable anti-tarnish material such as, for example, Au (Gold) or a water soluble organic material.

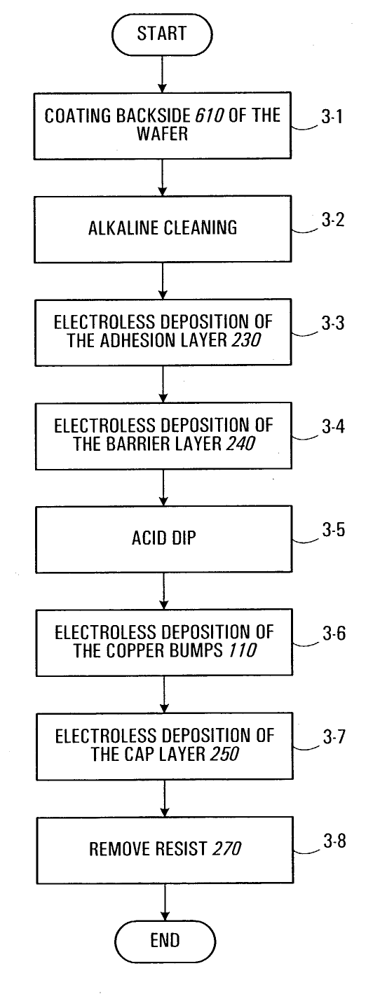

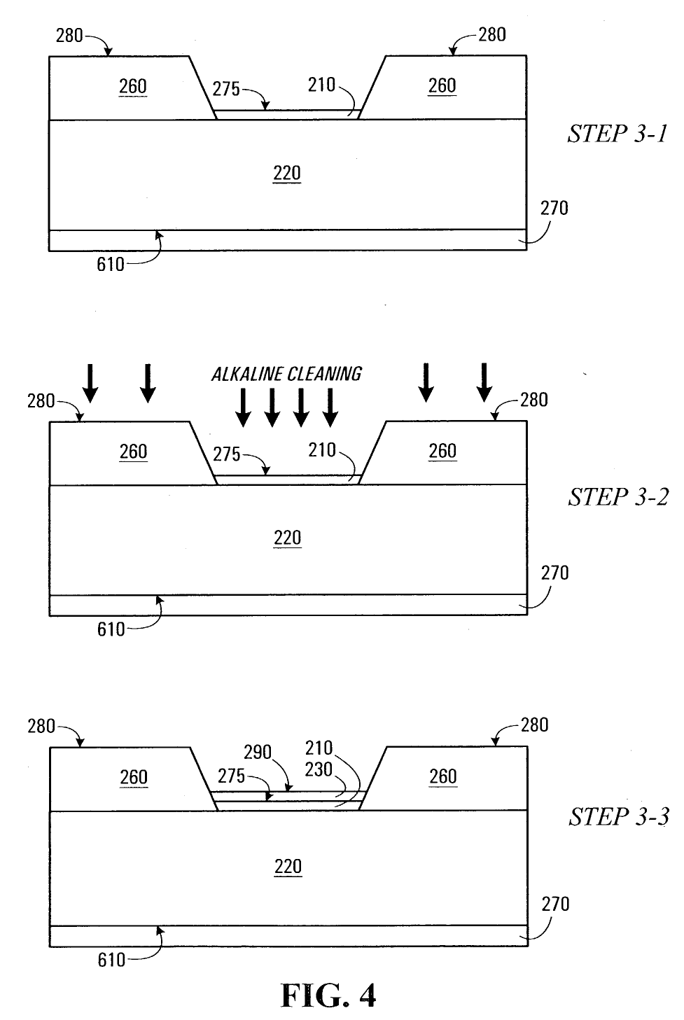

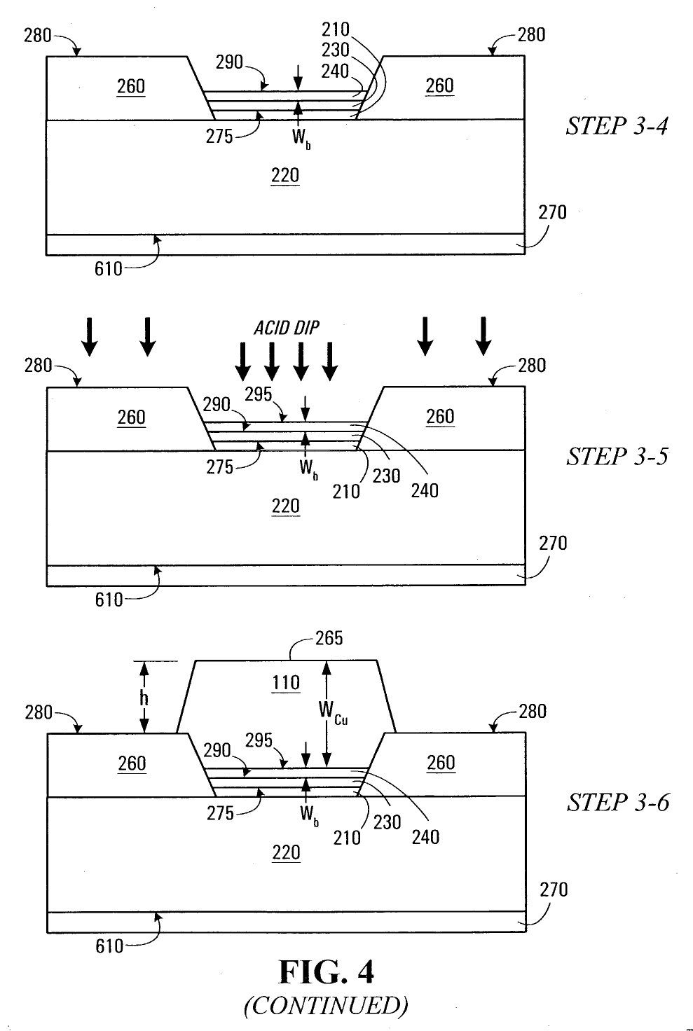

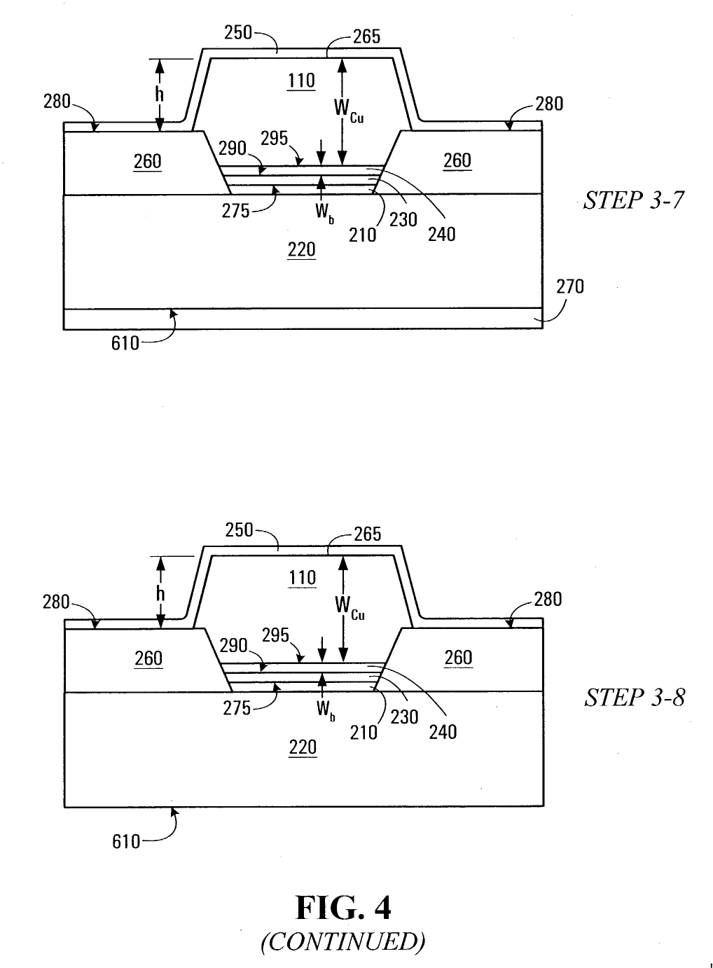

Referring to FIG. 3, shown is a flow chart of a process used to manufacture the copper bump 110 of FIG. 2. As shown in FIG. 4, at step 3-1 a wafer backside 610 is coated with a stable resist 270 prior to wet-chemical bumping. At step 3-2, the conductive pad 210 is cleaned in an alkaline cleaner, or more particularly an Aluminium cleaner, to remove oxide layers which can form on the conductive pad 210 anytime prior to step 3-2. At step 3-3, Zn atoms are deposited onto the conductive pad 210, using electroless deposition, to form the adhesion layer 230. The deposition of step 3-3 is performed by immersing the wafer containing the semiconductor chip 100 in an adhesive plating solution thereby subjecting the conductive pad 210 to the adhesive plating solution. The adhesive plating solution contains Zn⁺⁺ ions, which are selectively absorbed at the conductive pad 210. However, during step 3-3 some Zn⁺⁺ ions can absorb as particles of Zn onto a surface 280 of the passivation layer 260. At step 3-4, Pd atoms are deposited onto the adhesive layer 230, using electroless deposition, to form the barrier layer 240. The deposition of step 3-4 is performed by immersing the wafer containing the semiconductor chip 100 in a barrier plating solution thereby subjecting the adhesion layer 230 to the barrier plating solution. The barrier plating solution contains Pd⁺⁺ ions which are selectively absorbed at the adhesive layer 230. At step 3-5, the wafer is dipped in an acid dip solution thereby subjecting the passivation layer 260 to the acid dip solution for removing Zinc particles and/or Palladium particle that that may be physically attached to the surface 280 of the passivation layer 260. In addition, the acid dip solution is used to remove particles that contain both Zinc and Palladium, which may be physically attached to the surface 280. While the Zinc particles are removed from the surface 280, the Zinc particles in the adhesion layer 230 are protected by the barrier layer 240. At step 3-6, Cu atoms are deposited onto the barrier layer 240, using electroless deposition, to form a thin layer of Cu. Removal of the particles from the surface 280 at step 3-5 prevents Cu atoms from absorbing onto the passivation layer 260 during step 3-6. The electroless deposition of step 3-6 is performed by immersing the wafer containing the semiconductor chip 100 in a copper plating solution thereby subjecting the barrier layer 240 to the copper plating solution. The copper plating solution contains Cu⁺⁺ ions which are selectively absorbed at the barrier layer 240. At step 3-6, a reducing agent and a complexing agent are added to the copper plating solution for continued absorption of Cu⁺⁺ ions in a follow-up reaction to form the copper bump 110. Alternatively, in other embodiments of the invention, step 3-6 is split into two steps by adding the reducing agent and the complexing agent to the copper plating solution after absorption of the Cu⁺⁺ ions has begun. At step 3-7, an anti-tarnish material is deposited onto the copper bump 110, using electroless deposition, to form the cap layer 250. The deposition of step 3-7 is performed by immersing the wafer containing the semiconductor chip 100 in a cap plating solution containing an anti-tarnish chemical which is absorbed at the copper bump 110 and the surface 280 of the passivation layer 260. At step 3-8, the photoresist 270 at the backside 610 of the wafer is removed using any suitable well-known method.

The chemicals used in the process of FIG. 3 are listed in Table 1. However, it is to be understood that the invention is not limited to the chemicals listed in Table 1.

TABLE 1
Chemicals used in the process of FIG. 3.

| Solution | Remark |
|---|---|
| Resist 270 | Mac-Stop 9554 (MacDermid) |
| Alkaline Cleaner | Alumin 5975 (Enthon-OMI) |
| Adhesive Plating | Modified Alumin EN |
| Solution | (Enthone-OMI) |
| Barrier Plating | Produced in-house (see Table 2) |
| Solution | |
| Acid Dip Solution | 2-5% Sulfate Acid |
| | (or Nitric Acid) |
| Copper Plating | Produced in-house (see Table 3) |
| Solution | |
| Cap Plating Solution | Metex M667 (MacDermid) |

Each step of the process of FIG. 3 will now be described in more detail. At step 3-1, the resist 270 is Mac-Stop 9554 which is a solvent-based maskant especially designed for electroless deposition. The resist 270 is manually or chemically strippable and application can be done by spraying, dipping or brushing. The conditions for application of the resist 270 are listed in Table 4. In particular, application is performed at room temperature under dry conditions.

At step 3-2, Alumin 5975(Enthon-OMI) is selected as the alkaline cleaner. Alumin 5975(Enthon-OMI) is a moderate alkaline cleaner which has a very long bath lifetime and within its operating temperature range, which is between 25° C. and 75° C. as listed in Table 4, it does not etch out the conductive pad 210. At higher working temperatures, Alumin 5975(Enthon-OMI) has a small aluminium etching function. In FIG. 7, the surface profile of a surface 275 of the conductive pad 210 is shown having a smooth profile.

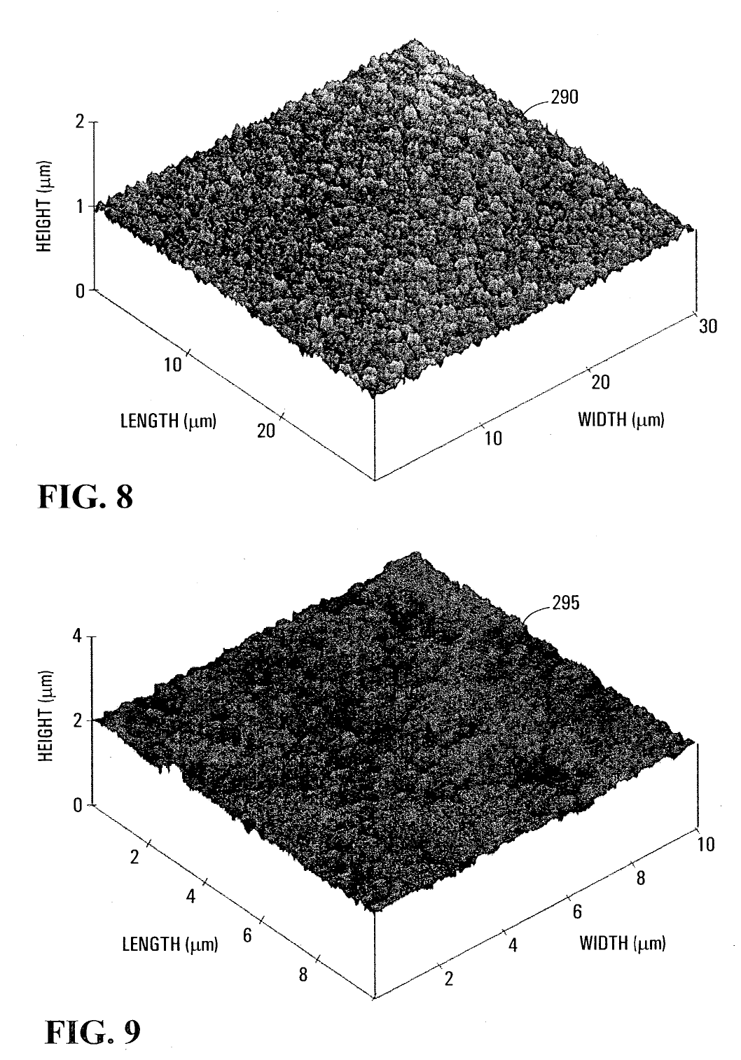

For step 3-3, 1 M (M=mol/L) of Sodium Hydroxide is added to Alumin EN to form the adhesive plating solution in which the Alumin EN concentration is kept within a range of 2.5-5%. As listed in Table 4, the wafer is immersed in the adhesive plating solution for 30 to 50 seconds at a temperature of approximately 25° C. The addition of Sodium Hydroxide reduces the rate of corrosion of the conductive pad 210, increases the lifetime of the adhesive plating solution, and allows Zinc particles at a surface 290 of the adhesion layer 230 to be very fine in size. The very fine Zinc particles provides a smooth surface profile for the surface 290 which, in turn, provides a smooth surface for deposition of the copper bumps 110. The surface 290 is shown having a smooth surface profile in FIG. 8. The invention is not limited to an adhesive plating solution containing Sodium Hydroxide and Alumin EN and in other embodiments of the invention, other alkalines, such as Potassium Hydroxide and an acid-based zincation chemical for example, are used.

The electroless deposition of step 3-3 is described by a combination two half-reactions. In a first half-reaction, Al atoms at the surface 275 of the conductive pad 210 are converted into Al⁺⁺⁺ ions, which form part of the adhesion plating solution. The half-reaction equation for the first half-reaction is given by

Al⁺⁺⁺+3e [symbol] Al. (1)

In a second half-reaction, Zn₊₊ ions in the adhesive plating solution are absorbed at the surface 275 and the half-reaction equation of the second half-reaction is given by

Zn⁺⁺+2e [symbol] Zn. (2)

According to the general Nernst equation, the electrode potential E_{M} of a solution is given by

E_{M}=E_{M}⁰+0.0592/n log[M⁺ⁿ] (3)

wherein n is the oxidation state of an ion M⁺ⁿ being reacted, [M⁺ⁿ] is the molar concentration of the ion M⁺ⁿ and E_{M}⁰ is a standard electrode potential. For the half-reaction of Equation (1), n=3, [M⁺ⁿ]=[Al⁺⁺⁺], E_{M}=E_{Al}, and E_{M}⁰=E_{Al}⁰=−1.56 V. For the half-reaction of Equation (2), n=2, [M⁺ⁿ]=[Zn⁺⁺], E_{M}=E_{Zn}, and E_{M}⁰=E_{Zn}⁰=−0.763 V.

The first and second half-reactions of Equations (1) and (2) are combined into a single reaction equation which is given by

Al+Zn⁺⁺→Zn+Al⁺⁺⁺. (4)

As such, while Al atoms at the surface 275 of the conductive pad 210 are being converted into Al⁺⁺⁺ ions that form part of the adhesive plating solution, Zn⁺⁺ ions from the adhesive plating solution are selectively absorbed at the surface 275 to form the adhesive layer 230.

At step 3-3, when the wafer containing the semiconductor chip 100 is first immersed in the adhesive plating solution, E_{Al}<E_{zn}, the reaction is autocatalytic and proceeds to build-up the adhesion layer 230.

At step 3-4, the electroless deposition is performed by immersing the wafer containing the semiconductor chip 100 in the barrier plating solution containing Pd⁺⁺ ions, or equivalently, Palladium (II) ions. As listed in Table 4, the wafer is immersed for approximately 10 minutes at a temperature of approximately 80° C. The chemicals in the barrier plating solution and their respective concentrations are given in Table 2.

TABLE 2
Chemicals and respective concentrations of the barrier
plating solution.

| Chemicals in Barrier plating | | |
|---|---|---|
| solution | Concentration | |
| Palladium Chloride (PdCl₂) | 1.5-2 | g/L |
| and/or | | |
| Nickel Chloride (NiCl₂.6H₂O) | 0.6-1 | g/L |
| Sodium Phosphinate | 5-10 | g/L |
| Monohydrate (NaH₂PO₂.6H₂O) | | |
| (Reducing Agent) | | |
| Ammonium Chloride (NH₄Cl) | 20-30 | g/L |
| Ammonia | 150-180 | ml/L |
| Hydrogen Chloride | 4-6 | ml/L |

In embodiments in which the barrier layer 240 is made of Palladium the barrier plating solution contains Palladium Chloride. Alternatively, in embodiments in which the barrier layer 240 is made of Nickel the barrier plating solution contains Nickel. Finally, in embodiments in which the barrier layer 240 is made of Palladium and Nickel the barrier plating solution contains Palladium Chloride and Nickel Chloride.

Embodiments of the invention are not limited to Palladium Chloride as a source of Palladium ions and in other embodiments of the invention, the Palladium Chloride is replaced with Palladium Sulfate (PdSO₄). Similarly, embodiments of the invention are not limited to Nickel Chloride as a source of Nickel ions and in other embodiments of the invention, the Nickel Chloride is replaced with Nickel Sulfate (NiSO₄). The electroless deposition of step 3-4, is also described by two half-reactions. In a first half-reaction, Zn atoms at the surface 290 of the adhesion layer 230 are converted into Zn⁺⁺ ions which form part of the barrier plating solution. The half-reaction equation for the first half-reaction is given by Equation (2). In a second half-reaction, Pd⁺⁺ ions in the barrier plating solution are selectively absorbed at the surface 290 according to a half-reaction equation which is given by

Pd⁺⁺+2e [symbol] Pd (5)

with a standard electrode potential E_{M}⁰=E_{Pd}⁰=+0.83 V. For the half-reaction of Equation (5), the Nernst equation (3) is given by

E_{Pd}=E_{Pd}⁰+0.0592/2 log[N_{Pd}] (6)

where N_{Pd} is the concentration of Pd⁺⁺ ions in the barrier plating solution. Reaction Equations (2) and (5) are combined into a single reaction equation which is given by

Zn+Pd⁺⁺→Zn⁺⁺+Pd (7)

As such, while Zn atoms at the surface 290 of the adhesion layer 230 are being converted into Zn₊₊ ions that form part of the barrier plating solution, Pd⁺⁺ ions from the barrier plating solution are selectively absorbed at the surface 290 to form the barrier layer 240.

At step 3-4, when the wafer containing the semiconductor chip 100 is first immersed in the barrier plating solution, E_{Zn}<E_{Pd} and the reaction of Equation (7) is autocatalytic resulting in deposition of Pd atoms which form the barrier layer 240.

Without the follow-up reaction of step 3-4, the resulting barrier layer 240 has a width, W_{b}, of approximately 0.01 μm. The follow-up reaction of step 3-4 provides further absorption of Pd⁺⁺ ions to increase the width, W_{b}, of the barrier layer 240 to provide an effective barrier against copper atoms of the copper bumps 110. In the process of FIG. 3, the reducing agent being added to the barrier plating solution is H₂PO₂⁻ (Phosphinate Monohydrate). The Phosphinate Monohydrate is made present in the barrier plating solution by adding Sodium Phosphinate (NaH₂PO_{2.}6H₂O) to the barrier plating solution. The thickness, W_{b}, depends on the concentration of the reducing agent, or equivalently, the concentration of Sodium Phosphinate. For the barrier plating solution containing the chemicals of Table 2, the thickness, W_{b}, is increased up to a maximum thickness of approximately 10 μm. The reaction equation for the follow-up reaction is given by

Pd⁺⁺+H₂PO₂⁻+H₂O→HPO₃⁻⁻+3H⁺+Pd. (8)

In FIG. 9, a surface 295 of the barrier layer 240 is shown having a smooth profile.

At step 3-5, Palladium particles, Zinc particles and particle containing both Zinc and Palladium, which are trapped on the surface 280 of the passivation layer 260 are removed using the acid dip solution which contains an acidic chemical. The Acid dip step is also used to depress activation centers present on the passivation layer 260, which can attract Cu and lead to Cu growing on the passivation layer 260.

The passivation layer 260 is subjected to the acid dip solution by immersing the wafer in the acid dip solution for 10 to 15 seconds at room temperature, as listed in Table 4.

With regard to step 3-6, the chemicals used for the copper plating solution and their respective concentrations are listed in Table 3. As listed in Table 4, the wafer is immersed in the copper plating solution at a temperature between 80 and 90° C. and a pH level between 8.0 and 9.0.

TABLE 3
Chemicals and respective concentrations of the copper
plating solution.

| Chemicals in Copper Plating | | |
|---|---|---|
| Solution | Concentration | |
| Copper Sulfate | 10-20 | mg/L |
| or | | |
| Copper Surphonamides | | |
| EDTA-2Na | 40-50 | g/L |
| (Complexing Agent) | | |
| Tetramethylammonium (TMAH) | 10-40 | g/L |
| (Surface Control Agent) | | |
| 2,2′-dipyridyl | <200 | mg/L |
| (Surface Control Agent) | | |
| Formaldehyde | 30-50 | ml/L |
| (Reducing Agent) | | |
| Sodium Hydroxide | 20-30 | g/L |
| or | | |
| Potassium Hydroxide | | |

In one embodiment of the invention the copper plating solution contains Copper Sulfate and in another embodiment of the invention the copper plating solution contains Copper Surphonamides. Both Copper Sulfate and Copper Surphonamides provide Copper ions in the barrier plating solution. In one embodiment of the invention the copper plating solution contains Sodium Hydroxide and in another embodiment of the invention the copper plating solution contains Potassium Hydroxide. The Sodium Hydroxide and the Potassium Hydroxide are used to keep the copper plating solution in a strong alkali condition and, furthermore, Sodium ions from the Sodium Hydroxide equilibrate any charge imbalance in the copper plating solution.

In one embodiment, the copper plating solution contains Copper Sulfate which provides Cu⁺⁺ (Copper) ions that are selectively absorbed at the surface 295 of the barrier layer 240. The reaction in step 3-6 is given by

Cu⁺⁺+2e [symbol] Cu (9)

with a standard electrode potential E_{Cu}⁰=+0.34 V. The Cu reaction of Equation (9) is not autocatalytical and, at step 3-6, a reducing agent and a complexing agent are added to the copper plating solution. As listed in Table 3, the reducing agent is Formaldehyde and the complexing agent is EDTA-2Na. The reducing agent and the complexing agent provide a follow-up reaction to allow further absorption of Cu⁺⁺ ions to increase a thickness, W_{Cu}, of the copper bump 110. The follow-up reaction for the absorption of the Cu⁺⁺ ions is given by

Cu⁺⁺+2HCHO+4OH⁻→2HCOO⁻+2H₂O+H₂+Cu. (10)

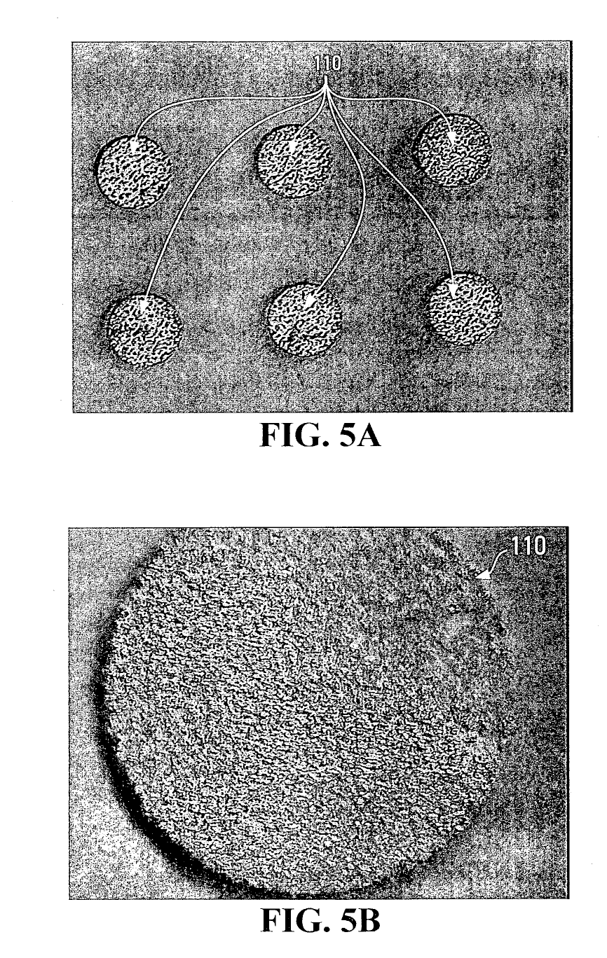

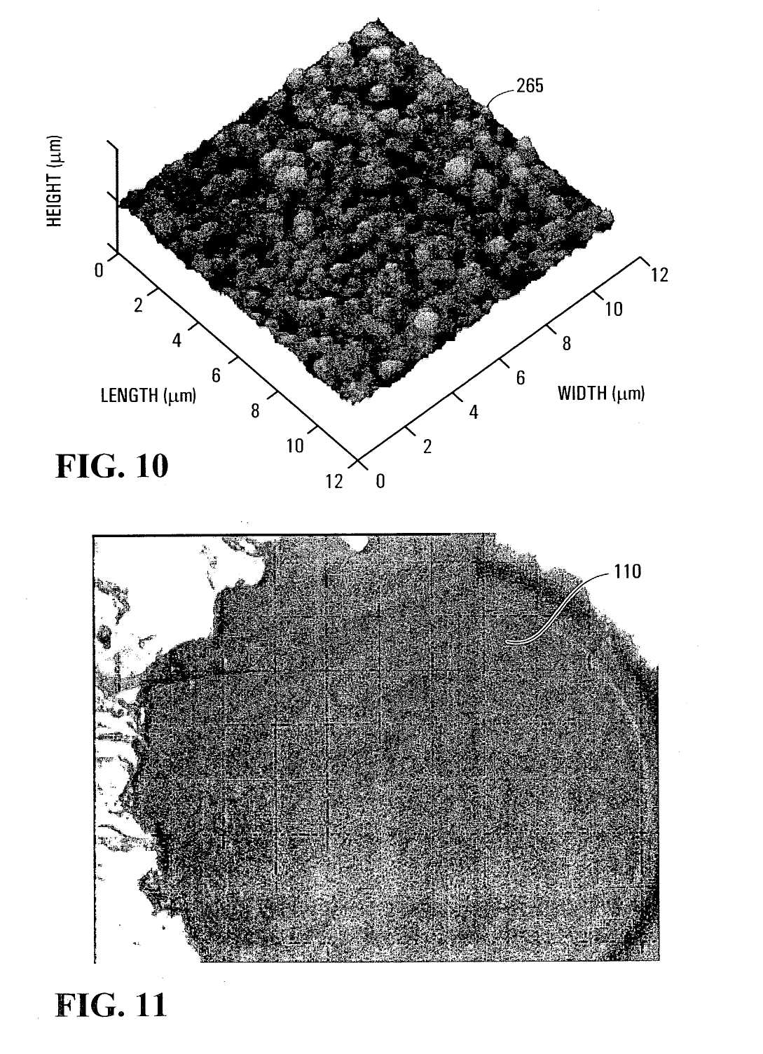

At step 3-6, a surface control agent is also added to the copper plating solution to provide a smooth surface profile of a surface 265 of the copper bumps 110. The surface control agent includes TMAH (Tetramethylammonium) and 2,2′-dipyridyl with each, TMAH and 2,2′-dipyridyl, being a stabilizer and a surfactant. In FIG. 5A, a top view of six copper bumps 110 of semiconductor chip 100 of FIG. 1 is shown as viewed from an optical microscope under a magnification of ×200. In FIG. 5B, an expanded view of one of the copper bumps 110 of FIG. 5A is shown as viewed from an optical microscope under a magnification of ×200. The surface 265 is also shown in FIG. 10 having a smooth surface profile.

At step 3-7, the wafer is immersed in the cap plating solution between 2 and 5 minutes at a temperature of approximately 25° C., as listed in Table 4. An anti-tarnish chemical, which is organic-based, is used as the cap plating solution resulting in the cap layer 250 being easily strippable by DI (De-Ionized) water. The cap layer 250 therefore provides a protective coating which can be easily stripped prior to having the microchip 100 mounted, for example, on a packaging substrate. In other embodiments of the invention other chemicals such as gold metal or other water soluble organic materials are used.

TABLE 4
Process parameters for the process of FIG. 3 used to
manufacture the copper bump 110 of FIG. 2.

| No | Process Step | Parameters | Remarks |
|---|---|---|---|
| 3-1 | Coating of | Room Temperature | |
| | Backside 610 | & Dry | |
| 3-2 | Alkaline | 25° C.-75° C., | |
| | Cleaning | 0.5-1.5 mins | |
| 3-3 | Electroless | 25° C. | For deposition in |
| | Deposition of | 30-50 sec | one or two steps |
| | Adhesion Layer | | |
| | 230 | | |
| 3-4 | Electroless | ˜80° C. | Acidic solution |
| | Deposition of | ˜10 mins | |
| | Barrier Layer | | |
| | 240 | | |
| 3-5 | Acid Dip | Room Temperature | |
| | | 10-15 sec | |
| 3-6 | Electroless | 80-90° C. | The time depends on |
| | Deposition of | ph: 8.0-9.0 | the required height |
| | Copper Bumps | | of the copper bump |
| | 110 | | |
| 3-7 | Electroless | 25° C. | |
| | Deposition of | 2-5 mins | |
| | Cap Layer 250 | | |

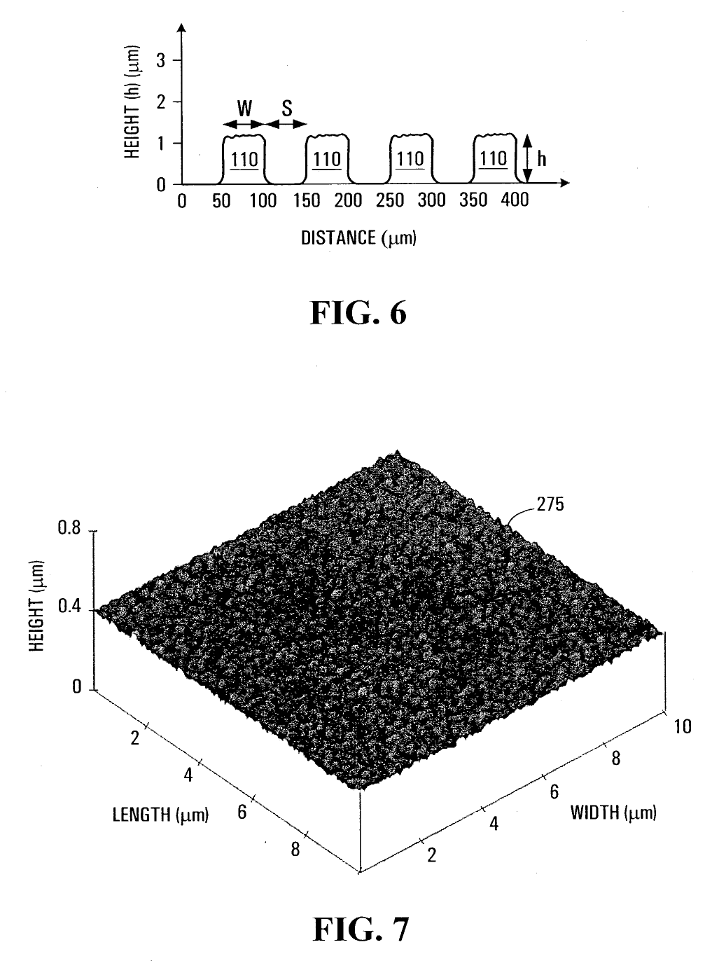

Referring to FIG. 6, shown is a graph of the height of the copper bumps 110 of the semiconductor chip 100 of FIG. 1 plotted as a function of distance along the semiconductor chip, the height being measured using a stylus profilometer. In particular, the height, h, of the copper bumps 110 is measured from the surface 280 of the passivation layer 260 and is plotted as a function of distance along axis 120. The bumps 110 have a width W of approximately 50 μm, a height h of approximately 1.15 μm for a plating time of only 10 min, and are separated by a distance S of approximately 50 μm. With reference back to step 3-6, a longer deposition time further increases the height h without significant change in shape of the bumps 110.

Referring to FIG. 11, shown is a photo of the copper bump 110 of FIG. 5B after having applied upon it a shear by a Shear Tester. In particular, while the copper bump 110 is totally distorted after applying the shear, it is still firmly attached to the conductive pad 210.

Numerous modifications and variations of the present invention are possible in light of the above teachings. It is therefore to be understood that within the scope of the appended claims, the invention may be practised otherwise than as specifically described herein.

We claim:

1. A process for producing copper bumps on a semiconductor wafer incorporating a plurality of semiconductor devices, the semiconductor wafer also having a passivation layer having openings and conductive pads, within the openings, in contact with the semiconductor devices, the process comprising the steps of:
performing electroless deposition of a conductive adhesive material onto the conductive pads to form adhesion layers;
performing electroless deposition of a conductive metal onto the adhesion layers to form barrier layers;
subjecting the passivation layer to an acid dip solution to remove any particles containing at least one of the conductive adhesive material and the conductive metal, which may be attached to the passivation layer; and
performing electroless deposition of Copper onto the barrier layers to form the copper bumps.

2. A process according to claim 1 comprising applying a resist on a backside of the semiconductor wafer prior to the step of performing electroless deposition of a conductive adhesive material onto the conductive pads to form adhesion layers.

3. A process according to claim 1 comprising removing oxidation layers on the conductive pads using an alkaline cleaner prior to the step of performing electroless deposition of a conductive adhesive material onto the conductive pads to form adhesion layers.

4. A process according to claim 1 wherein the step of performing electroless deposition of a conductive adhesive material onto the conductive pads to form adhesion layers comprises electrolessly depositing Zinc onto the conductive pads.

5. A process according to claim 4 wherein the electrolessly depositing Zinc onto the conductive pads comprises immersing the semiconductor wafer in an adhesive plating solution containing Zn⁺⁺ (Zinc⁺⁺) ions and allowing the Zn⁺⁺ ions to absorb onto the conducting pads in a reaction with Al (Aluminium), the conductive pads comprising Al.

6. A process according to claim 1 wherein the step of performing electroless deposition of a conductive metal onto the adhesion layers to form barrier layers comprises electrolessly depositing Pd (Palladium) onto the adhesion layers.

7. A process according to claim 1 wherein the step of performing electroless deposition of a conductive metal onto the adhesion layers to form barrier layers comprises electrolessly depositing Ni (Nickel) onto the adhesion layers.

8. A process according to claim 6 wherein the electrolessly depositing Pd onto the adhesion layers comprises immersing the semiconductor wafer in a barrier plating solution containing Pd⁺⁺ ions and allowing the Pd⁺⁺ ions to absorb onto the adhesive layers by reacting with Zn, the adhesion layers comprising Zn.

9. A process according to claim 6 wherein the electrolessly depositing Pd onto the adhesion layers comprises immersing the semiconductor wafer in a barrier plating solution containing a reducing agent for electrolessly depositing additional Pd onto the adhesion layers in a follow-up reaction.

10. A process according to claim 1 wherein the step of subjecting the passivation layer to an acid dip solution to remove any particles containing at least one of the conductive adhesive material and the conductive metal, which may be attached to the passivation layer comprises subjecting the passivation layer to the acid dip solution wherein the acid dip solution contains a Sulfate Acid or a Nitric Acid.

11. A process according to claim 1 wherein the step of subjecting the passivation layer to an acid dip solution to remove any particles containing at least one of the conductive adhesive material and the conductive metal, which may be attached to the passivation layer comprises subjecting the passivation layer to the acid dip solution to depress any active centers that may be present on the passivation layer.

12. A process according to claim 1 wherein the step of performing electroless deposition of Copper onto the barrier layers to form the copper bumps comprises immersing the semiconductor wafer in a copper plating solution containing copper ions, one of Sodium Hydroxide and Potassium Hydroxide, a complexing agent and a reducing agent.

13. A process according to claim 1 further comprising performing electroless deposition of an anti-tarnish chemical to produce a cap layer over the copper bumps and the passivation layer.

14. A semiconductor chip incorporating a plurality of semiconductor devices, the semiconductor chip also having a passivation layer having openings and conductive pads, within the openings, in contact with the semiconductor devices for providing contacts between the semiconductor devices and outside circuitry, within each one of the openings the semiconductor chip comprising:
an adhesion layer of a conductive adhesive material in contact with a respective one of the conducting pads;
a barrier layer of a conductive metal in contact with the adhesion layer; and
a layer of Copper in contact with the barrier layer, the layer of Copper forming a copper bump.

15. A semiconductor chip according to claim 14 wherein the conducting pads comprise Aluminium.

16. A semiconductor chip according to claim 14 wherein the adhesion layer comprises Zinc.

17. A semiconductor chip according to claim 16 wherein the barrier layer comprises Palladium or Nickel.

18. A semiconductor chip according to claim 14 wherein the conducting pads comprise Aluminium, the adhesion layer comprises Zinc and the barrier layer comprises Palladium or Nickel.

19. A semiconductor wafer comprising a plurality of semiconductor chips according to the semiconductor chip of claim 14.

20. A plating solution for electrolessly depositing Copper onto a layer of Nickel or Palladium, the plating solution comprising:
Copper ions for a reaction with the Nickel or Palladium for deposition of Copper; and
an alkaline, a complexing agent and a reducing agent for additional deposition of the Copper in a follow-up reaction.

21. A plating solution according to claim 20 comprising Copper Sulfate or Copper Surphonamides for providing the Copper ions in the plating solution.

22. A plating solution according to claim 20 wherein the alkaline comprises Sodium Hydroxide or Potassium Hydroxide.

23. A plating solution according to claim 20 comprising a surface control agent for providing a smooth surface of the Copper being deposited.

24. A plating solution according to claim 23 wherein the surface control agent comprises Tetramethylammonium and 2,2′-dipyridyl.

25. A plating solution according to claim 20 wherein the complexing agent is EDTA-2Na and the reducing agent is Formaldehyde.

26. A plating solution for electrolessly depositing a layer of Nickel or Palladium onto a layer of Zinc, the plating solution comprising:
Nickel or Palladium ions for a reaction with the Zinc for deposition of the Nickel or Palladium; and
a reducing agent for additional deposition of the Nickel or Palladium in a follow-up reaction.

27. A plating solution according to claim 26 comprising Nickel Chloride or Nickel Sulfate to provide the Nickel ions.

28. A plating solution according to claim 26 comprising Palladium Chloride or Palladium Sulfate to provide the Palladium ions.

29. A plating solution according to claim 26 comprising Ammonium Chloride, Ammonia and Hydrogen Chloride.

30. A plating solution according to claim 26 wherein the reducing agent comprises Sodium Phosphinate Monohydrate.
